(19) United States
(12) Patent Application Publication
(10) Pub. No.: US 2025/0050426 A1
(43) Pub. Date: Feb. 13, 2025

(54) COATED CUTTING TOOL

(71) Applicant: WALTER AG, Tubingen (DE)

(72) Inventors: Wolfgang ENGELHART, Tubingen (DE); Korbinian KULZER, Tubingen (DE); Veit SCHIER, Tubingen (DE); Torbjorn SELINDER, Tubingen (DE)

(21) Appl. No.: 18/721,945

(22) PCT Filed: Oct. 10, 2022
(86) PCT No.: PCT/EP2022/078060

§ 371 Date: Jun. 20, 2024

(30) Foreign Application Priority Data
Dec. 21, 2021 (EP) 21216688.8

(51) Int. Cl. B23B 27/14; C23C 14/06; C23C 14/35; C23C 14/58

(52) U.S. Cl. CPC B23B 27/148; C23C 14/0641; C23C 14/35; C23C 14/5873; B23B 2228/10

(57) ABSTRACT

A coated cutting tool includes a substrate including cubic boron nitride and a binder phase including TiC_{y}N_{1-y}, wherein 0≤y≤1. The binder phase contains impurities of aluminium expressed as a net intensity ratio of Al to Ti, and/or tungsten expressed as a net intensity ratio of W to Ti, and/or TiB₂ expressed as a ratio of the net peak height of the TiB₂ peak to the net peak height of the TiCN peak, and/or α-alumina expressed as a ratio of the net peak height of the α-alumina peak to the net peak height of the TiCN peak. A coating is deposited on the substrate and includes at least one nitride composed of a nitride of one or more elements belonging to group 4-6 of the periodic table of elements, or a nitride of Al and/or Si together with one or more elements belonging to group 4-6.

The present invention relates to a coated cutting tool comprising a coating on a cubic boron nitride (cBN)-based substrate, and a method for preparation thereof.

### BACKGROUND OF THE INVENTION

Coated cutting tools with a cubic boron nitride-based substrate for machining inter alia hardened steel such as hardened ball bearing steels are well-known in the art. Conventionally prepared tools comprise cBN-based substrates wherein the cBN grains are dispersed in a Ti(C,N) binder phase. The Ti(C,N) binder phase generally contains impurities of, for example, W compounds, TiB₂ and α-alumina. It has now been found this may result in reduced toughness and wear resistance. Such impurities may be unintentionally incorporated or added during the processing of raw materials or formed in the sintering process when the cBN grains and the binder phase are exposed to high pressure and temperature conditions in order to produce sintered composite bodies. Subsequent grinding of the sintered composite bodies containing a binder phase with such impurities, into cBN based substrates, impairs the surfaces which often results in reduced adhesion of a deposited coating to the substrate.

PVD-coated substrates are known to benefit from improved wear resistance properties compared to uncoated substrates. However, the adhesion of PVD coatings is not always satisfactory resulting in limited life span. In the art, it is taught to use interlayers between the substrate and the coating comprising nonmetallic, metallic or even interdiffused layers in order to improve the adhesion. This means that a PVD coating is not deposited on the substrate such that it is in direct contact therewith. Such interlayers are generally weak and therefore the bonding strength is not at optimum. It would therefore be desirable to further improve the adhesion between the substrate and the coating to extend the tool life. An objective of the present invention is thus to improve the adhesion of a coating without using interlayers, in particular a (Ti,Al)N coating deposited onto a cBN-based substrate, such as a coating deposited by a PVD method. A further objective of the invention is to impart improved wear resistance, life span and toughness to the coated cutting tool. An additional objective is to reduce the diffusion of workpiece material into the coating.

### The Invention

The present invention relates to a coated cutting tool comprising
i) a substrate comprising cubic boron nitride (cBN) and a binder phase comprising TiC_{y}N_{1-y}, wherein 0≤y≤1 wherein the binder phase contains impurities of
   a) aluminium expressed as a net intensity ratio of Al to Ti in the substrate below 0.50 as measured by Energy Dispersive X-ray Analysis (EDX); and/or
   b) tungsten expressed as a net intensity ratio of W to Ti in the substrate below 0.035; and/or
   c) TiB₂ expressed as a ratio of the net peak height of the TiB₂ (101) peak to the net peak height of the TiCN (200) peak being less than 0.09 as measured by XRD; and/or
   d) α-alumina expressed as a ratio of the net peak height of the α-alumina (116) peak to the net peak height of the TiCN (200) peak being less than 0.06 as measured by XRD;
ii) a coating deposited on the substrate comprising at least one layer composed of a nitride of one or more elements belonging to group 4, 5 or 6 of the periodic table of elements, or a nitride of Al and/or Si together with one or more elements belonging to group 4, 5 or 6 of the periodic table of elements.

According to one embodiment, the binder phase contains impurities of at least b) and d) as described above.

According to one embodiment, the cubic boron nitride comprised in the substrate is present in an amount ranging from 20 to 75, such as from 25 to 70 or 30 to 70, preferably from 40 to 70, and most preferably from 50 to 70 or 55 to 70% by volume based on the total volume of the substrate. The term TiCN (200) peak as used herein regards TiCN being TiC_{0.7}N_{0.3}.

According to one embodiment, at least 70% by volume, preferably at least 80% by volume, and most preferably at least 90% by volume or at least 95% by volume or all hard material comprised in the substrate is cubic carbon nitride (cBN).

Preferably, the binder phase is based on TiC_{y}N_{1-y}, wherein e.g. 0.4 s y s 0.9 or 0.6 s y s 0.8, with possible additions of transition metal carbides, nitrides or carbonitrides. According to one embodiment, the binder phase comprises from 80 to 100, more preferably from 90 to 95% by volume of TiC_{y}N_{1-y}, wherein y<1.

According to another embodiment, the binder phase comprises from 80 to 100, more preferably from 90 to 95% by volume of TiC.

According to one embodiment, the binder phase comprises from 80 to 100, more preferably from 90 to 95% by volume of TiN.

According to one embodiment, the grains of cBN in the binder phase have a bimodal size distribution with average grain sizes ranging from 0.1 to 1.2 μm and 2 to 6 μm, preferably from 0.2 to 0.6 μm and 3 to 5 μm respectively. By means of a bimodal size distribution within the specified ranges, increased toughness may be obtained.

In many conventional substrates, impurities, including W from processing equipment and 0 from atmosphere or blending fluids, are incorporated during raw material processing and sintering of the composite body, and a small amount of Al is typically added as a sintering aid. This leads to the formation of W containing impurities and of inter alia TiB₂ and α-Al₂O₃ being formed in the binder phase when exposed to high temperature and high pressure conditions during sintering.

It has been found that, in particular certain levels of these impurities, have a negative impact on adhesion of coatings to the substrate and therefore also the tool life of coated cutting tools.

According to one embodiment, the impurity of oxygen expressed as a net intensity ratio of 0 to Ti in the substrate is below 0.036 or below 0.030 or substantially 0 or above 0.005 or above 0.010 while being below any upper limit as specified herein as measured by Energy Dispersive X-ray Analysis (EDX).

According to one embodiment, the impurity of tungsten expressed as a net intensity ratio of W to Ti in the substrate is below 0.030 or below 0.020 or below 0.010, such as below 0.005 or below 0.0028, or below 0.0026 or substantially 0 or above 0.0010 or above 0.0015 while being below any upper limit as specified herein as measured by Energy Dispersive X-ray Analysis (EDX).

According to one embodiment, the impurity of aluminium expressed as a net intensity ratio of Al to Ti in the substrate is below 0.49 or below 0.48 or below 0.47 or below 0.46 or substantially 0 or above 0.05 or above 0.20 or above 0.30 while being below any upper limit as specified herein as measured by Energy Dispersive X-ray Analysis (EDX).

XRD measurements of the substrate according to the invention have shown that virtually no reflection of TiB₂ and weak diffraction from α-alumina occur with respect to the sintered composite body which indicates no or substantially no content of TiB₂ and limited contents of α-alumina.

According to one embodiment, TiB₂ expressed as a ratio of the net peak height of the TiB₂ (101) peak to the net peak height of the TiCN (200) peak is less than 0.07, or less than 0.05 or less than 0.03 or more preferably less than 0.02 or substantially 0 or above 0.005 while being below any upper limit as specified herein as measured by XRD.

According to one embodiment, the α-alumina expressed as a ratio of the net peak height of the a-alumina (116) peak to the net peak height of the TiCN (200) peak is less than 0.056 or less than 0.055 or less than 0.054 or less than 0.053 or less than 0.052 or less than 0.051 or less than 0.050 or less than 0.040 or substantially 0 or above 0.01 or above 0.02 while being below any upper limit as specified herein as measured by XRD.

According to one embodiment, the surface roughness Rz_{cBN} of the substrate ranges from 0.60 μm to 3 μm, preferably from 0.60 μm to 1.5 μm, and most preferably from 0.75 μm to 1.00 μm as measured in FIB-SEM cross section by Peak-to-Valley height measurement.

According to one embodiment, the surface of the substrate has a coverage of cubic boron nitride of at least 55% and less than 95% of the surface area as measured by the line intersecting method.

According to one embodiment, the surface of the substrate has a coverage of cubic boron nitride of at most 95%, for example at most 90% or at most 85% or at most 80% or at most 75% of the surface area as measured by the line intersecting method.

According to one embodiment, the hardness of the substrate surface ranges from 2200 to 3000, preferably 2500 to 2800, most preferably from 2600 to 2700 Vickers. The hardness is determined by making 100 measurements along the cutting edge of the substrate with a maximum load of 2 mN.

According to one embodiment, the indentation module EIT ranges from 500 to 700 GPa, preferably from 530 to 600 GPa.

According to one embodiment, the content of the binder phase ranges from 25 to 75% by volume based on the total volume of the substrate.

According to one embodiment, the coated cutting tool further comprises a coated supporting body, wherein the substrate and the coating as specified herein constitute a cutting edge tip attached to the supporting body.

According to one embodiment, the cutting edge tip is provided as a brazed tip on the supporting body.

According to one embodiment, the cutting edge tip is brazed to said supporting body via a braze joint covering an area between said supporting body and said substrate.

The term “sintered composite body” as used herein is meant to include any sintered body composed of a binder phase comprising TiC_{y}N_{1-y} and a hard material of at least cubic boron nitride (cBN). Preferably, the “sintered composite body” has been precision ground to form a substrate by means of for example diamond grinding wheels using digitally controlled precision grinding machines well known in the art, or other known methods of forming a substrate such as laser manufacturing. In the grinding process or other method of forming a substrate, the surface of the cBN sintered composite body may often become damaged by chipping of the cBN grains or by smearing of the binder phase, to the detriment of for instance toughness or coating adhesion.

In one preferred embodiment, the substrate is attached to a supporting body by means of brazing or sintering before grinding. According to one embodiment, the supporting body may comprise one or several further hard materials such as tungsten carbide (WC).

The term “surface” in the context of the sintered composite body is meant to include the zone extending perpendicularly from the surface in contact with a deposited coating towards the bulk of the sintered composite body. The thickness of the zone can be compared with the grain size of the polishing material and may amount e.g. up to about 3000 nm or 1500 nm, such as up to 1200 nm, or 500 nm or up to 200 nm.

According to one embodiment, said at least one nitride layer is preferably CrN, TiN, CrAlN, TiAlN, NbN, TiSiN, more preferably CrN, CrAlN, TiAlN, NbN, and TiSiN, and most preferably TiAlN or expressed as TiₓAl₁₋ₓN, wherein x ranges from 0.3 to 0.7.

According to one embodiment, the coating further comprises a ZrN layer deposited on said at least one nitride layer.

According to one embodiment, the adhesion p of said at least one nitride layer to the substrate is <0.6, preferably <0.5 or <0.35 or <0.2 as measured by the Calo test.

According to one embodiment, the grains of said at least one nitride such as (Ti,Al)N layer has an average columnar grain width, measured at a distance of up to 2 μm from the lower interface of the (Ti,Al)N layer, i.e. 2 μm from the substrate surface, of from 80 to 250 nm, preferably from 80 to 175 nm, and most preferably from 100 to 150 nm.

According to one embodiment, said at least one nitride, such as (Ti,Al)N, has a thickness of 0.1 to 15 μm, for example 0.5 to 10 μm, preferably 1 to 6 μm, most preferably from 2 to 4 μm or 2 to 3 μm.

According to one embodiment, a sub-layer type in a multilayer of said at least one nitride, such as a (Ti,Al)N sub-layer type in a multilayer, preferably has an average thickness of 1 to 100 nm, preferably from 1.5 to 50 nm, and most preferably from 2 to 20 nm.

According to one embodiment, in the case of different nitride sublayer types, such as (Ti,Al)N sublayer types, the ratio between the average thicknesses of the different (Ti,Al)N sublayer types is from 0.5 to 2, preferably from 0.75 to 1.5.

According to one embodiment, the nitride layer such as a (Ti,Al)N layer has a Vickers hardness of ≥3000 HV (15 mN load), preferably 3500 to 4200 HV (15 mN load). The hardness measurement was performed by means of a hardness measuring device PICODENTOR® HM500 of Helmut Fischer GmbH, Sindelfingen-Maichingen, Germany, using a Vickers pyramid at a maximum load of 15 mN, with a loading duration and unloading duration of 20 sec and a holding duration of the load of 5 sec. The evaluation of the measurements was carried out according to the Oliver-Pharr method.

According to one embodiment, the coating comprises a (Ti,Al)N layer being either a single monolithic layer or a multilayer of two or more alternating (Ti,Al)N sub-layer types different in their composition which sub-layers may have an average thickness ranging from e.g. 1 to 100 nm.

According to one embodiment, the grains of (Ti,Al)N are columnar, preferably having an increasing grain width of (Ti,Al)N with increasing thickness of the (Ti,Al)N layer.

The invention also relates to a method of preparing a coated cutting tool comprising
i) providing a substrate by ion etching a sintered composite body comprising cubic boron nitride (cBN) and a binder phase comprising TiC_{y}N_{1-y} to an average depth of at least 200 nm corresponding to an average surface removal of at least 200 nm of the sintered composite body, wherein the binder phase contains impurities of
   a) aluminium expressed as a net intensity ratio of Al to Ti in the substrate below 0.50 as measured by Energy Dispersive X-ray Analysis (EDX); and/or
   b) tungsten expressed as a net intensity ratio of W to Ti in the substrate below 0.035; and/or
   c) TiB₂ expressed as a ratio of the net peak height of the TiB₂ (101) peak to the net peak height of the TiCN (200) peak being less than 0.09 as measured by XRD; and/or
   d) the α-alumina expressed as a ratio of the net peak height of the α-alumina (116) peak to the net peak height of the TiCN (200) peak being less than 0.06 as measured by XRD;
ii) a coating deposited on the substrate comprising at least one layer composed of a nitride of one or more elements belonging to group 4, 5 or 6 of the periodic table of elements, or a nitride of Al and/or Si together with one or more elements belonging to group 4, 5 or 6 of the periodic table of elements.

According to one embodiment, the binder phase comprises impurities of b) and d).

According to one embodiment, the surface coverage of cubic boron nitride is at least 55%, such as at least 65% or at least 75% of the surface area as measured by the line intersecting method.

According to one embodiment, the surface of the substrate is ion etched to a degree such that the coverage of cubic boron nitride still is at most 95%, for example at most 90% or at most 85% or at most 80% or at most 75% of the surface area as measured by the line intersecting method.

According to one embodiment, the ion etching is performed by means of plasma ion etching.

According to one embodiment, the time of ion etching is in a range from 30 to 300 minutes, for example 60 minutes to 200 minutes or 60 to 150 minutes or 90 to 150 minutes. According to one embodiment, the time of etching ranges from 60 to 120 minutes.

According to one embodiment, the sintered composite body is etched to an average depth >200 nm, preferably from 200 to 1500 nm, more preferably from 400 to 1200 nm, most preferably from 600 to 1000 nm such as from 700 to 900 nm.

According to one embodiment, said at least one layer composed of a nitride is deposited on the substrate by means of high power impulse magnetron sputtering (HIPIMS).

According to one embodiment, the coating is deposited on the substrate by a PVD method, for example cathode sputtering (sputter deposition), cathodic vacuum arc deposition (arc PVD), ion plating, electron beam evaporation and laser ablation. Cathode sputtering, such as magnetron sputtering, reactive magnetron sputtering and high power impulse magnetron sputtering (HIPIMS) and arc vapor deposition are among the PVD processes which are most frequently used for the coating of cutting tools which may be used for depositing the coating. According to one embodiment, the coating is preferably deposited by means of High Power Impulse Magnetron Sputtering (HIPIMS).

In high power impulse magnetron sputtering (HIPIMS), the magnetron is operated at high current densities in the pulsed mode, resulting in an improved layer structure in the form of denser layers, in particular due to an improved ionization of the sputtered material. The current densities at the target in the HIPIMS process typically exceed those of the classical DC-MS. Depending on the material, by means of HIPIMS, an ionization of up to 100% of the sputtered particles can be achieved. At the same time, the short-term high powers and discharge current densities, respectively, acting on the target impart an increased degree of ionization which can alter the growth mechanism and the bonding of the layers to the material below and thus has an influence on the layer properties.

In the HIPIMS process, fine crystalline as well as columnar crystalline layer structures can be achieved, which are characterized by an improved wear behavior and longer service lives, related thereto, in comparison to DC-MS layers.

According to one embodiment, a ZrN layer may be deposited on said at least one nitride layer, such as a (Ti,Al)N layer, which may consist of a single layer or several layers of ZrN arranged on top of each other. If the covering layer consists of several layers of ZrN arranged on top of each other, these are deposited from one or more Zr-targets, however, in several steps of the HIPIMS process having different deposition parameters.

According to one embodiment, one or more layers of ZrN having an overall thickness of 1 nm to 700 nm, preferably from 100 nm to 300 nm is deposited on said at least one layer composed of a nitride such as a (Ti,Al)N layer.

The ZrN layer may have a decorative function but may also serve as wear detection thus indicating by the wear thereof if the tool has already been used and with which wear it has been used. In case there are no further layers arranged on top of the Zr layer, the ZrN covering layer gives the tool a golden yellow color which may be varied between different color shades by adjusting the HIPIMS process parameters. For example, by respectively adjusting the nitrogen partial pressure in the HIPIMS process, the brightness of the golden yellow shade may be varied. The deposition of a ZrN layer in the HIPIMS process, similar as the TiAlN layer, has advantages in terms of process control from the deposition of the functional layer to the covering layer. Moreover, the provision of the ZrN layer has tribochemical advantages in machining, in particular of titanium alloys being used for example in the aerospace industry and in machining stainless steels. For the deposition of the ZrN layer, it is not necessary to apply to the sputtering targets consisting of the material to be deposited for the ZrN layer.

Preferably, a TiAlN is deposited by varying the partial pressure of nitrogen gas during a first part and second part of the process whereby the nitrogen has a higher partial pressure during a second part, and lower partial pressure during a first part of the process. WO2016/128504 further discloses process conditions how TiAlN may be deposited which also may be applied in the present invention.

According to one embodiment, the deposition of any coating layers is performed at a peak power density of >0.2 kW/cm², preferably >0.4 kW/cm², most preferably >0.7 kW/cm², preferably at a peak current density of >0.2 A/cm², more preferably >0.3 A/cm², and most preferably >0.4 A/cm²; and preferably at a maximum peak voltage of from ≥1000 V.

According to one embodiment, a (Ti,Al)N layer and optionally any additional layer is deposited by means of high power impulse magnetron sputtering (HIPIMS), wherein power pulses are applied in the coating chamber to each sputtering target consisting of material to be deposited, which power pulses transfer an amount of energy to the sputtering target that exceeds a maximum power density in the pulse of ≥1000 W/cm².

In a further embodiment, a nitride layer such as a (Ti,Al)N layer and any further layer deposited on the (Ti,Al)N layer are applied by means of high power impulse magnetron sputtering (HIPIMS) whereby power pulses are applied in the coating chamber to each sputtering target consisting of material to be deposited, which power pulses have discharge current densities in the pulse of ≥1 A/cm², preferably ≥3 A/cm².

According to one embodiment, the maximum peak voltage ranges from 1000 to 3000 V, preferably from 1500 to 2500 V.

According to one embodiment, the substrate temperature during the magnetron sputtering is preferably from 350 to 600° C., or from 400 to 500° C.

According to one embodiment, the DC bias voltage used in the HIPIMS process is from 20 to 150 V, preferably from 30 to 100 V.

According to one embodiment, the average power density in the HIPIMS process ranges from 20 to 100 W·cm⁻², preferably from 30 to 75 W·cm⁻².

According to one embodiment, the pulse length used in the HIPIMS process ranges from 2 μs to 200 ms, preferably from 10 μs to 100 ms, more preferably from 20 μs to 20 ms, and most preferably from 40 μs to 1 ms.

According to one embodiment, the cutting tool is an insert, a drill or an end mill.

The invention also relates to the use of the coated cutting tool for machining hardened steel, e.g. ball bearing steel or other hardened steel having a hardness higher than 40 HRc, preferably higher than 55 HRc, most preferably higher than 59 HRc.

### Methods

EDX: The contents of aluminium, oxygen, and tungsten in the binder phase of the cBN substrate were estimated and represented as a net intensity ratio relative to the titanium content by Energy Dispersive X-Ray Spectroscopy (EDX) analysis. The binder phase analysis was done on metallographically polished sections in the scanning electron microscope using an electron energy of 15 keV and by using an EDAX analytic system with an Octane Plus X-ray detector (Energy resolution 130 eV at the MnK peak, Detector area 10 mm², Peltier cooling). The net integrated respective peak intensities of W_{M}, O_{K} and AI_{K} were divided with the net integrated Ti_{K} peak in order to represent the contents of the respective elements W, O and Al as a net intensity ratio relative to the titanium content.

XRD (Seifert GE 3003PTS, Cu X-Ray source, polycapillary pinhole 1 mm, parallel plate colliminator 0.4°, Energy dispersive detector Meteor OD); In order to estimate the content of the impurity phases Al₂O₃ and TiB₂ in the TiCN binder phase, x-ray diffractograms were recorded in Bragg-Brentano geometry. The net peak height of the α-alumina (116) peak and the TiB₂ (101) peak were divided by the net peak height of the TiCN (200) peak to obtain the impurity phase relative peak height ratios as a measure of the impurity phase content of the binder phase.

### Calo Analysis

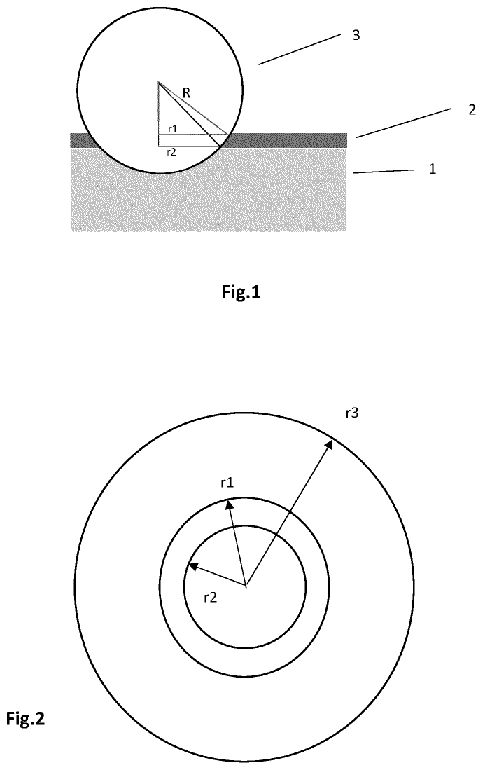

The Calo test was performed by means of a rotating metal bullet (3) as illustrated in FIG. 1 grinding a deepening (=calo) in the coating. From the calo, a light microscopy image is acquired. The metal bullet (3) lies between the insert, fixed by a magnet, and a spindle. Rotation of the spindle rotates the bullet (3) which grinds a hole in the coating using a 1 μm diamond suspension. The spindle rotation speed and grinding time are selected to make a hole through the coating such that the substrate (1) becomes visible in the center of the calo. A sharp borderline between the substrate (1) and the coating (2) indicates a good adhesion. A shredded boarder line between coating (2) and substrate (1) indicates a bad adhesion.

The diameter of the innermost visible substrate was approximately in the range of d=200 μm to 450 μm. Measurements were performed close to the corner and about 1 mm away from each edge. When determining the quality of the adhesion, radii r1 and r2 were measured. r1 corresponds to a radius of the coating at a distance t from the interface of the substrate and the coating at radius r2. By measuring r1 and r2 and knowing the radius of the rotating bullet R (1.5 cm in the present examples), the thickness t extending perpendicularly from the substrate-coating interface at a radius r2 to the radius r1 can be calculated (see FIGS. 1 and 2) according to formula (1)

$$t = sqrt ( {R}^{2} - r {1}^{2} ) - sqrt ( {R}^{2} - r {2}^{2} ) \qquad ( 1 )$$

The radius r2 is determined by observing the area of torn material such that it is surrounded by radii r1 and r2.

The total thickness of the total coating corresponds to the difference between a radius r3 and r2, i.e.:

$${t}_{total coating} = r 3 - r 2 \qquad ( 2 )$$

To be independent of the size of the calo ring formed, a ratio p is defined as the coating thickness of r2 divided by the total thickness corresponding to r3 of the coating, i.e.

$$ρ = t / {t}_{total coating} \qquad ( 3 )$$

The lower the value of p, the better the adhesion.

### Line Intersecting Method

The surface coverage of cBN grains on the uncoated substrate was estimated by drawing lines of 60 μm measuring length on a scanning electron micrograph of suitable magnification, for example 2000×, and then marking all line segments that bisect the cBN grains. The combined lengths of all these line segments were then added and divided by the total line length to obtain a cBN coverage number. A total of 5 lines were drawn and the surface coverage of the cBN grains was calculated as the mean of the 5 cBN coverage numbers.

### Cross Section Analysis

A Zeiss Crossbeam 540 FIB (Focused Ion-Beam analysis) instrument was used to produce cross sections of the cBN substrate by ion beam milling using Ga ions. The surface roughness of the substrate was determined by measuring the Peak-to-Valley distance Rz_{cBN} perpendicular to the substrate surface in cross sections over a measurement length of 25.3 μm. The peak and valley as used for the measurement (height measurement) correspond to the highest peak and lowest valley respectively over the measured length.

### EXAMPLE 1

The commercially available substrates DHA650 from Element Six and SBS600 from Iljin Diamond as specified below were treated by means of ion etching and subsequently in a coating step at process conditions as set out in table 6. The ion etching was performed in an Oerlikon Balzers Ingenia system. The ion etching rate was 7.5 nm/minute for all samples etched.
Machine type: Balzers Ingenia S3P
Temperature: 430° C.
Bias Voltage: 200V
Substrate rotation: 50%
Argon: 570 sccm
Power: 2×15 kW
Tpulse: 0.05 ms

### Substrates:

DHA650: 65% by volume of cBN and 35% by volume of TiCN based binder phase (TiC_{0.7}N_{0.3}) and inevitable impurities combined. The impurity net intensity ratios of impurities relative to the Ti as measured by EDX were as follows:

TABLE 1
DHA650 (invention)

| Element and | Net peak | Net intensity ratio |
|---|---|---|
| X-ray line | intensity (counts/s) | relative to Ti |
| O K | 24 | 0.034 |
| Al K | 321 | 0.453 |
| W M | 1.2 | 0.002 |
| Ti K | 708 | 1.000 |

The impurity phase relative peak heights as measured by XRD were as follows:

TABLE 2
Invention (DHA650)

| | | Impurity phase relative peak |
|---|---|---|
| XRD peak | Peak height (mm) | height |
| TiCN (200) | 120 | 1.000 |
| TiB₂ (101) | 2 | 0.017 |
| Al₂O₃ (116) | 6 | 0.050 |

and the surface coverage of CBN grains was measured by the line intersection method as follows (results in %):

TABLE 3
cBN coverage

| | Unetched | 15 Min etch | 105 Min etch |
|---|---|---|---|
| | substrate | comparison | invention |
| Measurement | (in %) | (in %) | (in %) |
| Line No: | | | |
| 1 | 43 | 53 | 74 |
| 2 | 48 | 43 | 88 |
| 3 | 56 | 47 | 76 |
| 4 | 65 | 53 | 81 |
| 5 | 52 | 65 | 73 |
| cBN coverage | 52.8 | 52.2 | 78.4 |
| mean | | | |
| Average etch depth | 0 nm | 112.5 nm | 787.5 nm |
| Rz_{cBN} | — | 0.49 μm | 0.89 μm |

SBS600 (ref. substrate): 60% by volume of cBN and 40% by volume of TiCN based binder phase and inevitable impurities combined. The impurity net intensity ratios relative to the Ti were as follows:

TABLE 4
Reference (SBS600)

| Element and | Net peak | Net intensity ratio |
|---|---|---|
| X-ray line | intensity (counts/s) | relative to Ti |
| O K | 31.8 | 0.041 |
| Al K | 434 | 0.558 |
| W M | 30.3 | 0.039 |
| Ti K | 778 | 1.000 |

The impurity phase relative peak heights as measured by XRD were as follows:

TABLE 5
Reference (SBS600)

| | | Impurity phase relative peak |
|---|---|---|
| XRD peak | Peak height (mm) | height |
| TiCN (200) | 135 | 1.000 |
| TiB₂ (101) | 14 | 0.104 |
| Al₂O₃ (116) | 9 | 0.067 |

### Coatings:

W: (Ti₄₀Al₆₀)N/ZrN
T DA(Ti₄₀Al₆₀)N/(Ti₇₅Si₂₅)N

The performance of the coated cutting tools was evaluated during continuous turning of 100CrMo7-3 steel, through-hardened to 62HRc. The cutting speed was 220 m/min, the depth of cut was 0.2 mm, and the feed rate 0.15 mm/rev. The wear mark on the flank face was measured and the end of the tool life was set to be at the time when the flank wear reached v_{b}=0.20 mm.

TABLE 6

| | | Ion | | | |
|---|---|---|---|---|---|
| | | etching | | Tool | |
| | cBN | time | | life | |
| Variant | substrate | (min) | Coating | (min) | Remark |
| Invention | DHA650 | 70 | W | 28 | Ti₄₀Al₆₀N/ZrN/Binder |
| | | | | | TiC/TiN |
| Comparative | SBS600 | 70 | W | 21 | |
| example | | | | | |
| (ref) | | | | | |
| Benchmark 1 | DHA650 | 15 | T | 19 | Ti₄₀Al₆₀N/TiSiN-based |
| | | | | | Baliq ® T (Oerlikon Balzers |
| | | | | | Coating Germany GmbH) |
| Benchmark 2 | SBS600 | 15 | T | 22 | |
| Reference 1 | SBS600 | | — | 18 | uncoated |
| Reference 2 | DHA650 | | — | 20 | uncoated |

As can be noted in table 1, the tool life of the invention DHA650/W (ion etching time 70 minutes) was 28 minutes which can be compared with DHA650/T (ion etching time 15 minutes) having a tool life of 19 minutes. As both the T and the W coatings had the same Ti₄₀Al₆₀N layer deposited on the substrate DHA650, the Wand T coatings are fully comparable. The same adhesion with the same treatment would thus be obtained for both the W and the T coatings having a Ti₄₀Al₆₀N layer directly in contact with the treated substrate. A difference of 9 minutes longer tool life (increase of 47%) was thus obtained by ion etching the DHA650 substrate for 70 minutes (corresponding to an average etching depth of 525 nm) instead of 15 minutes (112.5 nm average etching depth) with the indicated ion etching rate. The extended tool life was achieved due to the increased adhesion obtained when exposing the substrate to a longer ion etching time.

A further effect noted was that less flaking occurred in the DHA650 substrate/W coating (invention) than for the comparative example SBS600 substrate/T coating (ref).

Improved adherence was noted in the Calo test for DHA650/W (according to the invention) where a measured p value of ⅙ was obtained as opposed to the reference SBS600/T where the measured p value was ⅔. The longer tool life and improved adhesion that followed upon increased etching depth (as a direct effect of longer etching time with constant etching rate) and associated with a higher cBN surface coverage of the invention, was surprising inasmuch the person skilled in the art would have expected less adhesion for a coating deposited on cBN material in comparison to the adhesion obtained on the TiCN binder phase, i.e. a substrate surface having an increased cBN coverage.

The hardness of the etched substrate surfaces obtained by making 100 measurements along the cutting edge with a maximum load of 2 mN was according to the following:

| | | |
|---|---|---|
| 15 min etching | EIT = 456 GPa | HV = 2145Vickers |
| 105 min etching | EIT = 560 GPa | HV = 2650Vickers |

The etching effect was uniform on the flank, rake and edge.

1. A coated cutting tool comprising:
a substrate including cubic boron nitride (cBN) and a binder phase including TiC_{y}N_{1-y}, wherein 0≤y≤1, and wherein the binder phase contains impurities of
aluminium expressed as a net intensity ratio of Al to Ti in the substrate below 0.50 as measured by Energy Dispersive X-ray Analysis; and/or
tungsten expressed as a net intensity ratio of W to Ti in the substrate below 0.035; and/or
TiB₂ expressed as a ratio of a net peak height of a TiB₂ peak to a net peak height of a TiCN peak being less than 0.09 as measured by XRD; and/or
α-alumina expressed as a ratio of a net peak height of a α-alumina peak to a net peak height of the TiCN peak being less than 0.06 as measured by XRD; and
a coating deposited on the substrate, the coating including at least one layer composed of a nitride of one or more elements belonging to group 4, 5 or 6 of the periodic table of elements, or a nitride of Al and/or Si together with one or more elements belonging to group 4, 5 or 6 of the periodic table of elements.

2. The coated cutting tool according to claim 1, wherein a surface of the substrate has a coverage of cubic boron nitride of at least 55% and less than 95% of a surface area as measured by a line intersecting method.

3. The coated cutting tool according to claim 1, wherein a content of the cubic boron nitride in the substrate ranges from 25 to 75% by volume based on a total volume of the substrate.

4. The coated cutting tool according to claim 1, wherein the coating includes a ZrN layer deposited on the at least one nitride layer.

5. The coated cutting tool according to claim 1, wherein an adhesion of the at least one nitride layer to the substrate is <0.6 as measured by a Calo test.

6. The coated cutting tool according to claim 1, further comprising a supporting body, wherein the substrate and the coating constitute a cutting edge tip attached to the supporting body.

7. The coated cutting tool according to claim 6, wherein the cutting edge tip is provided as a brazed tip on the supporting body.

8. The coated cutting tool according to claim 6, wherein the cutting edge tip is brazed to the supporting body via a braze joint covering an area between the supporting body and the substrate.

9. The coated cutting tool according to claim 1, wherein the substrate has a roughness expressed as a peak-to-valley distance Rz_{cBN} ranging from 0.60 to 3 μm as measured by FIB-SEM cross section.

10. The coated cutting tool according to claim 1, wherein the binder phase contains impurities of
tungsten expressed as a net intensity ratio of W to Ti in the substrate below 0.035; and
α-alumina expressed as a ratio of a net peak height of the α-alumina peak to the net peak height of the TiCN peak being less than 0.06 as measured by XRD.

11. The coated cutting tool according to claim 1, wherein the coating deposited on the substrate includes at least one layer of TiAlN.

12. A method of preparing a coated cutting tool comprising:
providing a substrate by ion etching a sintered composite body including cubic boron nitride and a binder phase including TiC_{y}N_{1-y}, wherein 0≤y≤1 to an average depth of at least 200 nm corresponding to an average surface removal of at least 200 nm of the sintered composite body, wherein the binder phase contains impurities of
aluminium expressed as a net intensity ratio of Al to Ti in the substrate below 0.50 as measured by Energy Dispersive X-ray Analysis (EDX); and/or
tungsten expressed as a net intensity ratio of W to Ti in the substrate below 0.035 as measured by Energy Dispersive X-ray Analysis (EDX); and/or
TiB₂ expressed as a ratio of a net peak height of the TiB₂ peak to the net peak height of the TiCN peak being less than 0.09 as measured by XRD; and/or
α-alumina expressed as a ratio of a net peak height of a α-alumina peak to a net peak height of a TiCN peak being less than 0.06 as measured by XRD; and
a coating deposited on the substrate, the coating including at least one layer composed of a nitride of one or more elements belonging to group 4, 5 or 6 of the periodic table of elements, or a nitride of Al and/or Si together with one or more elements belonging to group 4, 5 or 6 of the periodic table of elements.

13. The method according to claim 12, wherein the ion etching is performed until a surface coverage of cubic boron nitride is at least 55% of a surface area as measured a the line intersecting method is obtained.

14. The method according to claim 12, wherein the ion etching is performed by plasma ion etching.

15. The method according to claim 12, wherein a time of etching ranges from 60 to 120 minutes.

16. The method according to claim 12, wherein the sintered composite body is etched to an average depth of 400 to 1200 nm.

17. The method according to claim 12, wherein the nitride layer is deposited on the substrate by high power impulse magnetron sputtering (HIPIMS).

18. The method according to claim 12, wherein the binder phase contains impurities of
tungsten expressed as a net intensity ratio of W to Ti in the substrate below 0.035 as measured by Energy Dispersive X-ray Analysis (EDX); and
the α-alumina expressed as a ratio of the net peak height of the α-alumina peak to the net peak height of the TiCN peak is less than 0.06 as measured by XRD.
